(19) United States
(12) Patent Application Publication
(10) Pub. No.: US 2015/0201528 A1
(43) Pub. Date: Jul. 16, 2015

(54) HEAT FIN FOR SMALL FORM-FACTOR PLUGGABLE OPTICAL TRANSCEIVER MODULE

(71) Applicant: Hubbell Incorporated, Shelton, CT (US)

(72) Inventors: Stephen Kent LEBO, Falls Church, VA (US); David Owen CORP, Clifton, VA (US)

(21) Appl. No.: 14/596,414

(22) Filed: Jan. 14, 2015

Related U.S. Application Data
(60) Provisional application No. 61/927,394, filed on Jan. 14, 2014.

(51) Int. Cl. H05K 7/20

(52) U.S. Cl. CPC H05K 7/20409

(57) ABSTRACT

A small-form pluggable optical transceiver (SFP) device comprising a housing including a main body that houses SFP components, and at least one protruding member that dissipates heat generated from the SFP components, wherein the protruding member extends beyond the main body of the housing.

This application claims the benefit of U.S. provisional application Ser. No. 61/927,394, filed Jan. 14, 2014, the entire contents of which are incorporated herein by reference.

### FIELD OF THE INVENTION

The present invention relates generally to a heat fin for an electrical component. More particularly, the present invention relates to a heat fin for a cable receiving electrical component that permits the component to dissipate more heat than a similar component without the heat fins and to provide strain relief to the received cable. Still more particularly, the present invention relates to a heat fin for a small form-factor pluggable (SFP) transceiver module.

### BACKGROUND OF THE INVENTION

Public communication carriers (hereinafter, “telcos”) are using more and more optical cable facilities to deliver services to customers because of the ability of optical cables to support high bandwidth. At a customer site, a means is often required to convert the optical signals to electrical signals, such as DS 1 or Ethernet. Small Form-factor Pluggable (SFP) transceiver modules are frequently used to provide this optical-to-electrical conversion. The SFP is plugged into a larger device, such as a Network Interface Device (NID) or router, which provide diagnostics, a means to power the SFP and one or more electrical, or optical, customer connections.

The SFP module is a compact, transceiver used for both telecommunication and data communications applications. The SFP transceiver module interfaces a mother board (e.g., a switch, router, NID, media converter or similar device) to a fiber optic or copper networking cable. SFP transceiver modules are designed to support SONET, Gigabit Ethernet, Fibre Channel, and other communications standards. The SFP module was designed after the GBIC interface, and allows greater port density (e.g., a greater number of transceivers per cm along the edge of a mother board) than the GBIC, which is why a SFP is also known as a mini-GBIC.

The SFP transceiver modules are typically inserted into a metal cage that is mounted on a printed circuit board (PCB). An exposed board edge near a first end of the SFP inserts into a mating connector attached to the PCB. A latch on the SFP locks into an opening in the metal cage to hold the assembly together. The data cable then connects to a second end of the SFP.

A conventional SFP module 1 is shown in FIGS. 1 and 25-27. A cable is connected to the SFP module 1 through a port 3 accessible through a front face 2 thereof defining the end of the module body. For fiber optic cables, port 3 may accommodate one or two optical connections. For example, a standard SFP accommodates a transmit fiber cable connection as well as a separate receive fiber cable connection. An alternate SFP configuration may have a single connection at port 3 for a bi-directional fiber cable that permits transmit and receive signals to be carried over the same single fiber. In a third SFP configuration, port 3 may be an RJ45 electrical connector to support direct connection of an electrical cable, such as an Ethernet cable. The optical cables are generally fragile and can be damaged if bent too sharply or crushed. SFP modules generate heat during operation. Additionally, SFP modules can fail when exposed to excessive heat. Equipment intended to use SFPs is generally designed utilizing standards, such as the multi-source agreement or MSA, which stipulates the maximum power that can be dissipated by a SFP. Such a standard helps to assure SFP thermal limits are not exceeded. However, when equipment is to be deployed in a hot environment or when additional circuitry is added within a SFP to provide, for example, additional diagnostics, thermal limits and/or heat dissipation limits may be exceeded and can potentially cause premature failure of the SFP. Accordingly, a need exists for a SFP module having adequate heat fins to substantially prevent overheating of the SFP module.

### SUMMARY OF THE INVENTION

An object of the present invention is to provide an improved SFP module configuration that facilitates heat dissipation from the SFP module.

In accordance with an aspect of an illustrative embodiment of the present invention, a heat fin is provided for a SFP module.

Still another aspect of the present invention is to provide a heat fin that is configured to provide strain relief for a cable or cables connected to a SFP module.

A further aspect of the present invention is to provide a small-form pluggable optical transceiver (SFP) device comprising a housing including a main body that houses SFP components, and at least one protruding member that dissipates heat generated from the SFP components and provides cable strain relief, wherein the protruding member extends beyond the main body of the housing.

Other objects, advantages and salient features of the invention will become apparent from the following detailed description, which, taken in conjunction with the annexed drawings, discloses preferred embodiments of the invention.

As used in this application, the terms “front,” “rear,” “upper,” “lower,” “upwardly,” “downwardly,” and other orientational descriptors are intended to facilitate the description of the exemplary embodiment of the present invention, and are not intended to limit the structure of the exemplary embodiment of the present invention to any particular position or orientation.

### BRIEF DESCRIPTION OF THE DRAWINGS

The above aspects and features of the present invention will be more apparent from the description for an exemplary embodiment of the present invention taken with reference to the accompanying drawings, in which:

FIG. 1 is a perspective view of a conventional small form-factor pluggable (SFP) optical transceiver module;

FIG. 2 is a perspective view of a SFP optical transceiver module having a heat fin in accordance with a first exemplary embodiment of the present invention;

FIG. 3 is a front and first end, upper perspective view of the SFP module of FIG. 2;

FIG. 4 is a first end elevational view of the SFP module of FIG. 2;

FIG. 5 is a front and first end, lower perspective view of the SFP module of FIG. 2;

FIG. 6 is a top plan view of the SFP module of FIG. 2;

FIG. 7 is a front elevational view of the SFP module of FIG. 2;

FIG. 8 is a bottom plan view of the SFP module of FIG. 2;

FIG. 9 is a front and second end, upper perspective view of the SFP module of FIG. 2;

FIG. 10 is a second end elevational view of the SFP module of FIG. 2;

FIG. 11 is a front and second end, lower perspective view of the SFP module of FIG. 2;

FIG. 12 is a front and first end, upper perspective view of a SFP optical transceiver module having a heat fin in accordance with a second exemplary embodiment of the present invention;

FIG. 13 is a first end elevational view of the SFP module of FIG. 12;

FIG. 14 is a front and first end, lower perspective view of the SFP module of FIG. 12;

FIG. 15 is a top plan view of the SFP module of FIG. 12;

FIG. 16 is a front elevational view of the SFP module of FIG. 12;

FIG. 17 is a bottom plan view of the SFP module of FIG. 12;

FIG. 18 is a front and second end, upper perspective view of the SFP module of FIG. 12;

FIG. 19 is a second end elevational view of the SFP module of FIG. 12;

FIG. 20 is a front and second end, lower perspective view of the SFP module of FIG. 12;

FIG. 21 is a perspective view of the SFP module of FIG. 12 with a pair of optical cables connected thereto;

FIG. 22 is a perspective view of a housing of the SFP module of FIG. 12;

FIG. 23 is a front elevational view of the housing of the SFP module of FIG. 22 with a latch in a first position;

FIG. 24 is a front elevational view of the housing of the SFP module of FIG. 22 with the latch in a second position;

FIG. 25 is a top plan view of the conventional SFP module of FIG. 1 without heat fins;

FIG. 26 is a first end elevational view of the SFP module of FIG. 1 without heat fins;

FIG. 27 is a front elevational view of the SFP module of FIG. 1 without heat fins;

FIG. 28 is a top plan view of the SFP module of FIG. 12;

FIG. 29 is a first end elevational view of the SFP module of FIG. 12;

FIG. 30 is a front elevational view of the SFP module of FIG. 12;

FIG. 31 is a front and second end, upper perspective view of a third embodiment of a SFP module;

FIG. 32 is a top plan view of the SFP module of FIG. 31;

FIG. 33 is a front elevational view of the SFP module of FIG. 31;

FIG. 34 is a first end elevational view of the SFP module of FIG. 31;

FIG. 35 is a bottom plan view of the SFP module of FIG. 31;

FIG. 36 is a front and first end, upper perspective view of the SFP module of FIG. 31;

FIG. 37 is a rear and second end, lower perspective view of the SFP module of FIG. 31;

FIG. 38 is a cutaway lower perspective view of the SFP module of FIG. 31;

FIG. 39 is a cross-sectional view of FIG. 32 taken along line A-A of FIG. 32 when the release member is in a free state and the housing is configured to be engaged with the cage;

FIG. 40 is a cross-sectional view of FIG. 32 taken along line A-A of FIG. 32 when the release member is depressed causing the housing to be configured to disengage from the cage; and

FIG. 41 is a cover of the SFP module of FIG. 31.

Throughout the drawings, like reference numerals will be understood to refer to like parts, components and structures.

### DETAILED DESCRIPTION OF ILLUSTRATIVE EMBODIMENTS

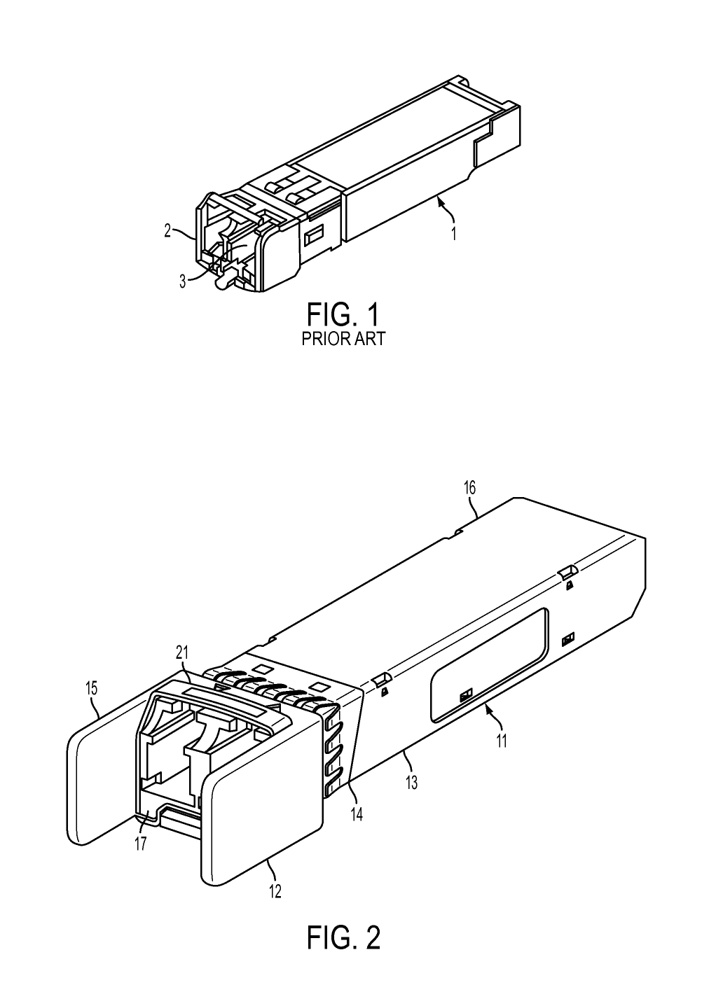

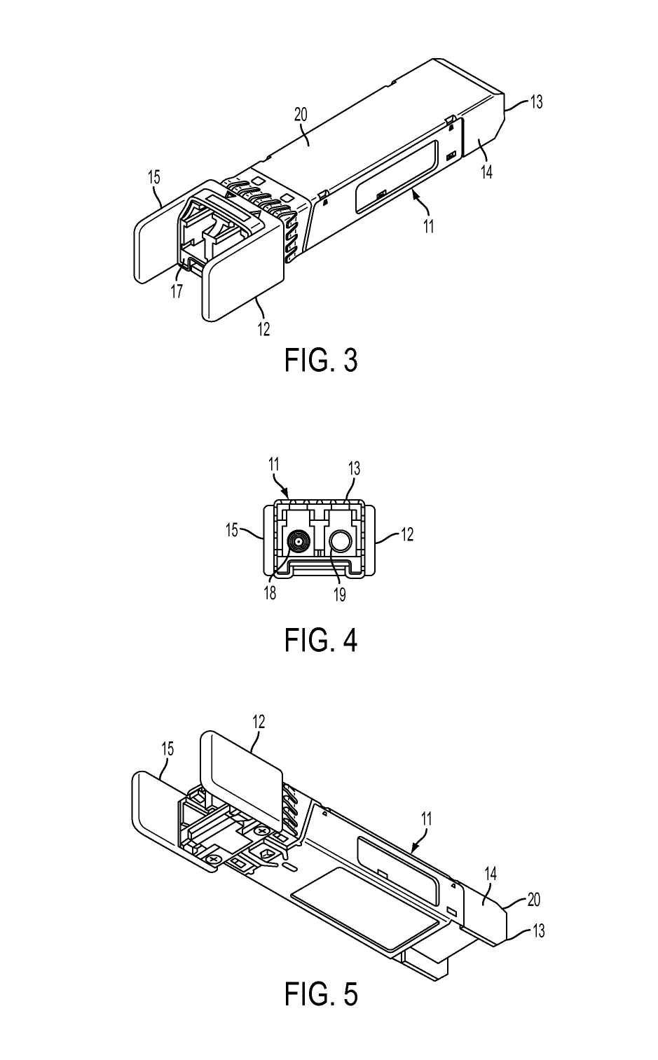

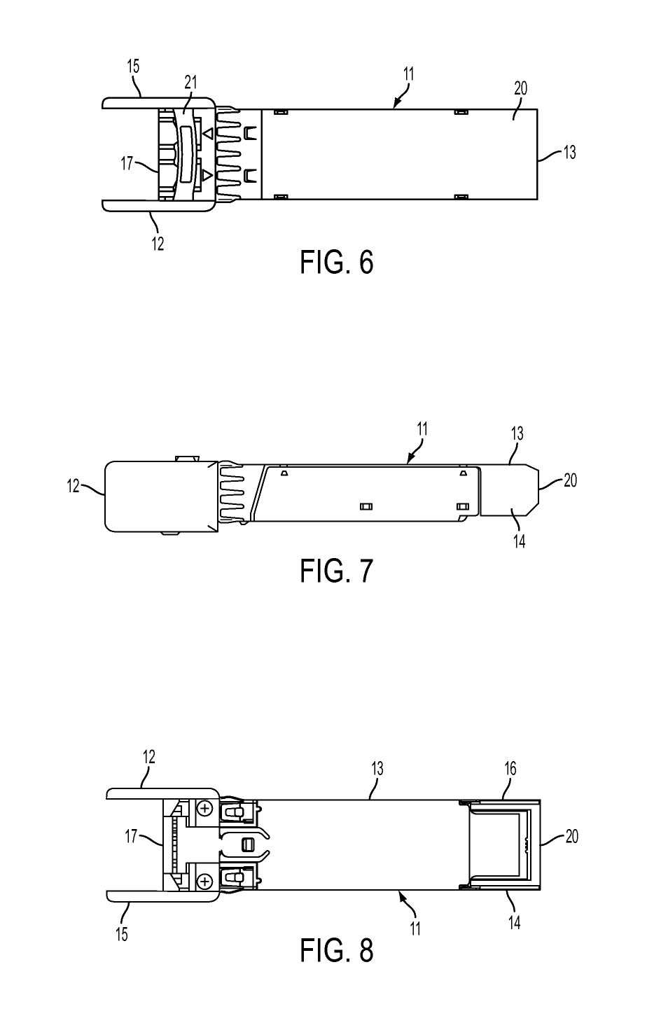

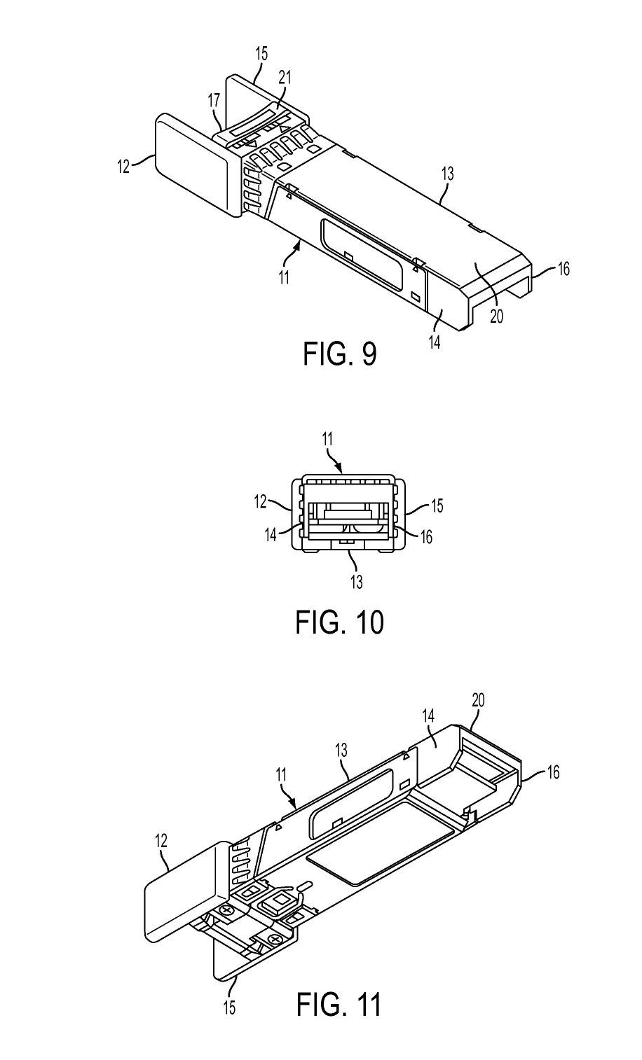

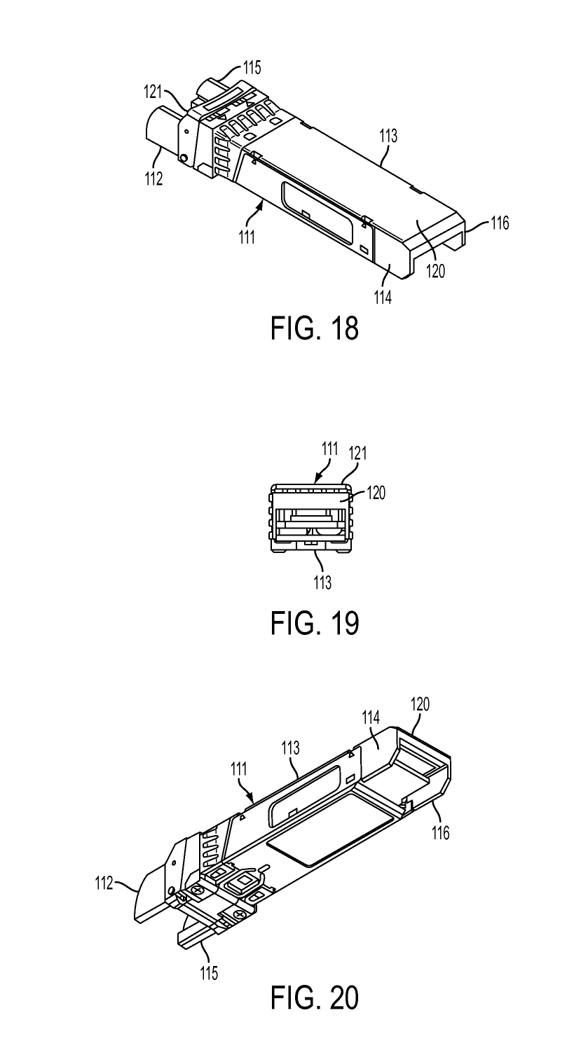

As shown in FIGS. 2-21, a small form-factor pluggable (SFP) optical transceiver module has a heat fin to substantially prevent overheating of the SFP module.

As shown in FIGS. 2-11, a first exemplary embodiment of a SFP module 11 includes a first heat fin 12 extending outwardly from a body 13 of the SFP module. The first fin 12 extends forwardly from a front surface 14 of the body 13. A second fin 15 extends forwardly from a rear surface 16 of the body 13 and is substantially parallel to the first fin 12. The fins 12 and 15 extend a substantial distance beyond a first end 17 of the body 13 of the SFP module 11. Ports 18 and 19 of the SFP module are accessible through the first end 17 to connect cables thereto. The fins 12 and 15 are substantially rectangular. Preferably, the first and second fins 12 and 15 are substantially identical. Because fiber optic cable connectors generally have an integral strain relief and the strain relief extends from the first end of the SFP module 11, the strain relief prevents the fiber cable or cables from being bent to the side. Therefore, the heat fins 12 and 15 do not impede routing of the fiber cable or cables extended from the first end of the SFP module 11.

The body 13 of the SFP module 11 includes a housing 20, which is preferably made of metal, such as an aluminum alloy. The first and second fins 12 and 15 are preferably unitarily formed as a single piece with the housing 20, such as by die casting.

A latch 21 is movably connected to the body 13 of the SFP module 11. The latch 21 is movable from a first position, as shown in FIG. 2, in which the SFP module is secured to a conventional mounting cage to a second position in which the SFP module is removable from the cage, as described in U.S. patent application Ser. No. 13/767,178, which is published as US 2014/0133124 and is hereby incorporated by reference in its entirety. The latch 21 is preferably rotatably connected to the housing 20 of the SFP module 11 in any suitable manner.

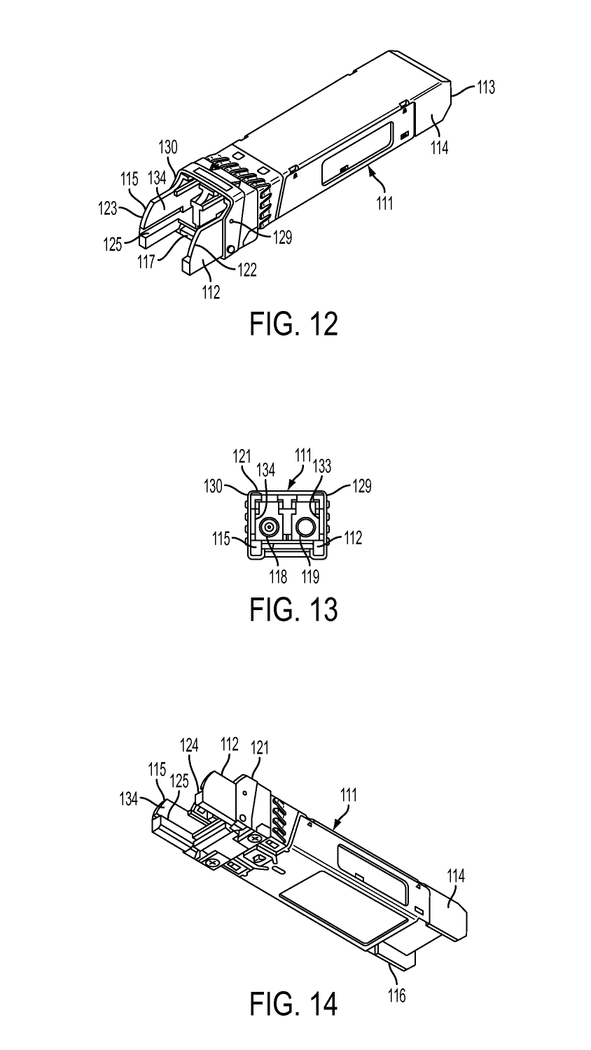

As shown in FIGS. 12-24, a second exemplary embodiment of a SFP module 111 includes a first heat fin 112 extending outwardly from a body 113 of the SFP module. The first fin 112 extends forwardly from a front surface 114 of the body 113. A second fin 115 extends forwardly from a rear surface 116 of the body 113 and is substantially parallel to the first fin 112. The fins 112 and 115 extend a substantial distance beyond a first end 117 of the body 113 of the SFP module 111. Ports 118 and 119 of the SFP module are accessible through the first end 117 to connect cables thereto. Because fiber optic cable connectors generally have an integral strain relief and the strain relief extends from the first end of the SFP module 111, the strain relief prevents the fiber cable or cables from being bent to the side. Therefore, the heat fins 112 and 115 do not impede routing of the fiber cable or cables extended from the first end of the SFP module 111.

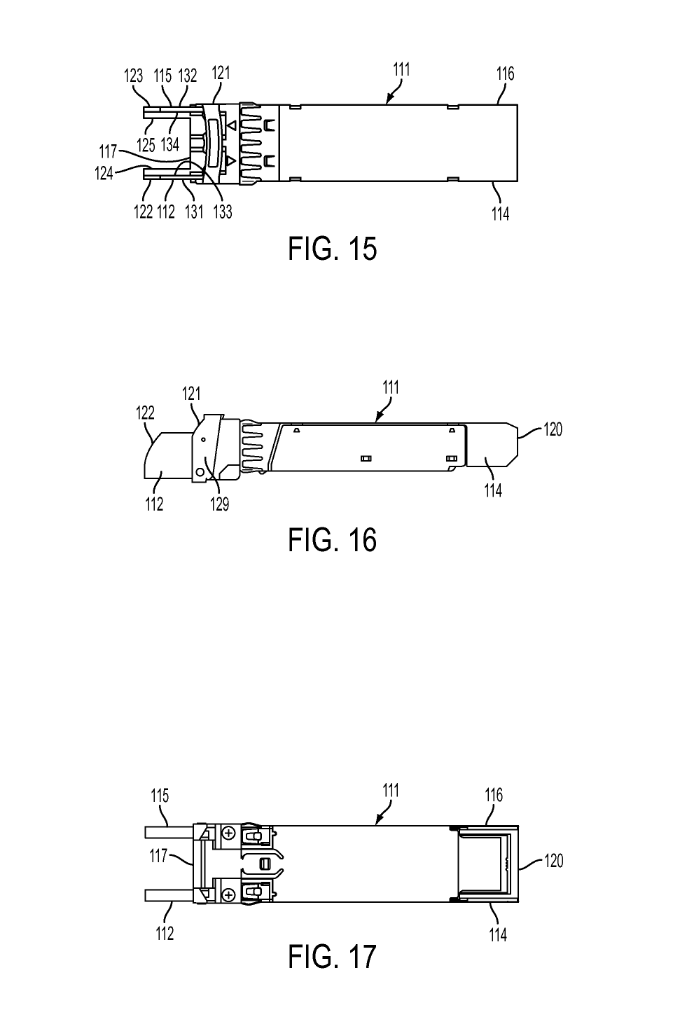

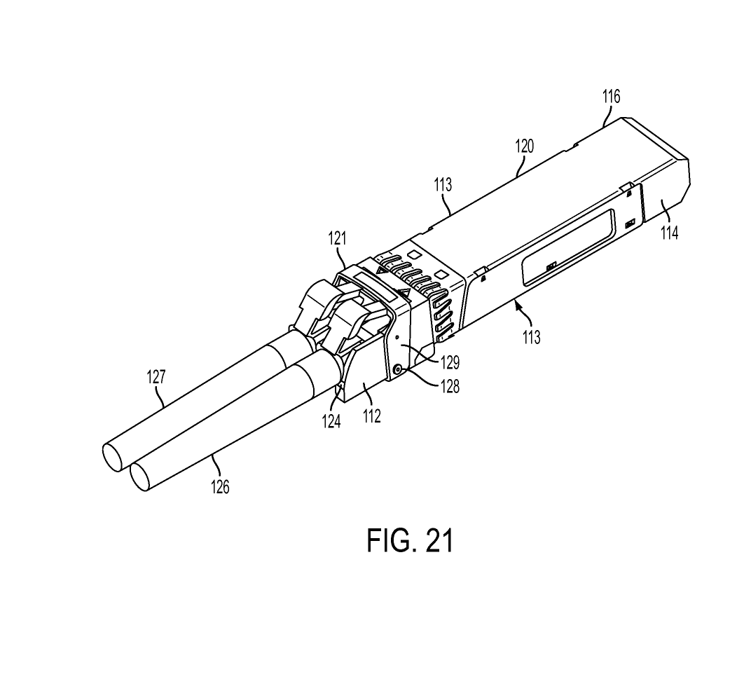

The fins 112 and 115 are substantially identical. Front edges 122 and 123 of each fin 112 and 115 are preferably arcuate, or radiused, to facilitate movement of a latch 121, as shown in FIGS. 12 and 22-24. Shoulders 124 and 125 extend rearwardly from the front edges 122 and 123 along inner surfaces 133 and 134 of the fins 112 and 115 to support cables 126 and 127, as shown in FIGS. 15, 21 and 22. The shoulders 124 and 125 substantially prevent sharp bends in the cables 126 and 127, as shown in FIG. 21, particularly at the connection to the SFP module 111. The shoulders 124 and 125 also facilitate aligning and guiding the cables 126 and 127 into the SFP module 111.

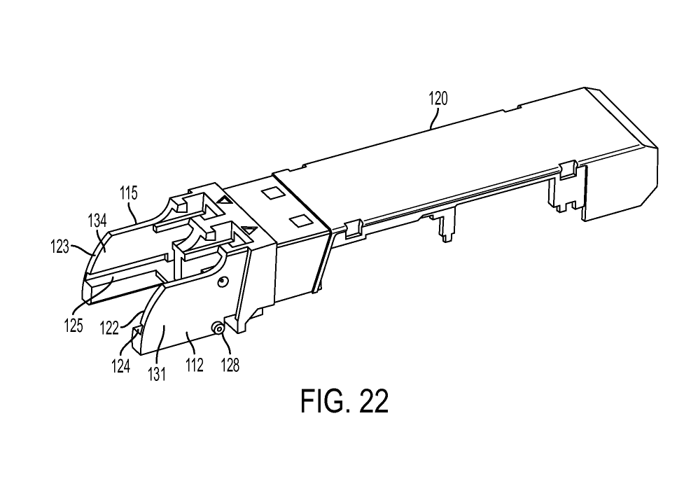

The body 113 of the SFP module 111 includes a housing 120, which is preferably made of metal, such as an aluminum alloy. The first and second fins 112 and 115 are preferably unitarily formed as a single piece with the housing 120, such as by die casting, as shown in FIG. 22.

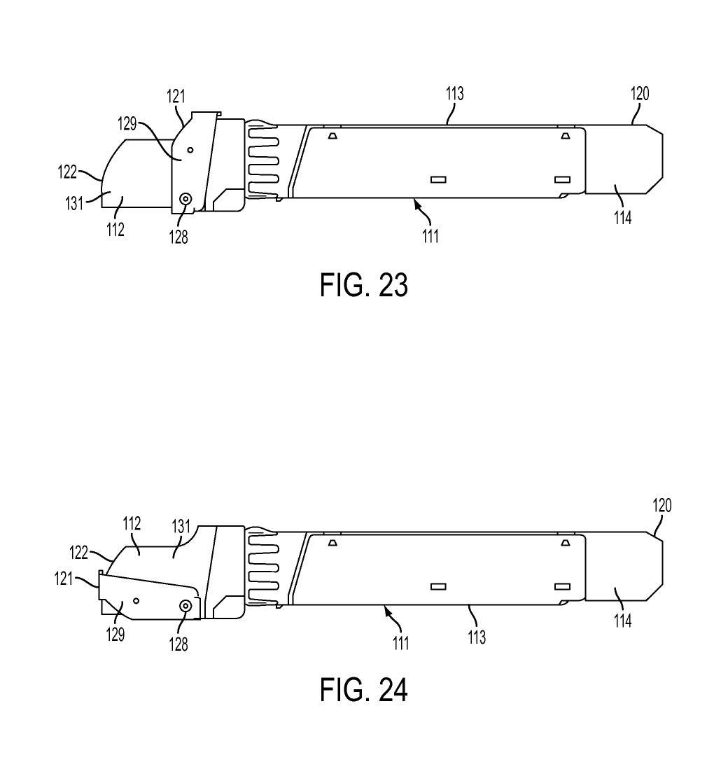

A latch 121 is movably connected to the body 113 of the SFP module 111, as shown in FIGS. 23 and 24. The latch 121 is movable from a first position, as shown in FIG. 23, in which the SFP module 111 is secured to a conventional mounting cage to a second position, as shown in FIG. 24, in which the SFP module is removable from the cage, as described in U.S. patent application Ser. No. 13/767,178, which is published as US 2014/0133124 and incorporated herein by reference in its entirety. The latch 121 is preferably rotatably connected to the housing 120 of the SFP module 11 in any suitable manner. The latch 121 can be rotatably connected to a hinge point 128 of the housing 120, as shown in FIGS. 22-24. As shown in FIGS. 23 and 24, the arcuate front edges 122 and 123 of the fins 112 and 115 facilitates rotation of the latch 121 between first and second positions (e.g., the edges are radiused to allow the latch release lever 121 to rotate 90 degrees from a starting position), thereby allowing the latch arms 129 and 130 to be mounted to outer surfaces 131 and 132 of the fins 112 and 115.

Additional circuitry and or faster processing speeds associated with some of SFP module implementations can generate additional heat, i.e., more heat than is specified within standards such as the multi-source agreement (MSA), during normal operation. The heat fins conduct and carry the additional generated heat away from the SFP module. The heat fins have a larger surface area to facilitate transferring the generated heat away from the SFP module to air flowing around the heat fins, thereby cooling the SFP modules and substantially preventing overheating thereof.

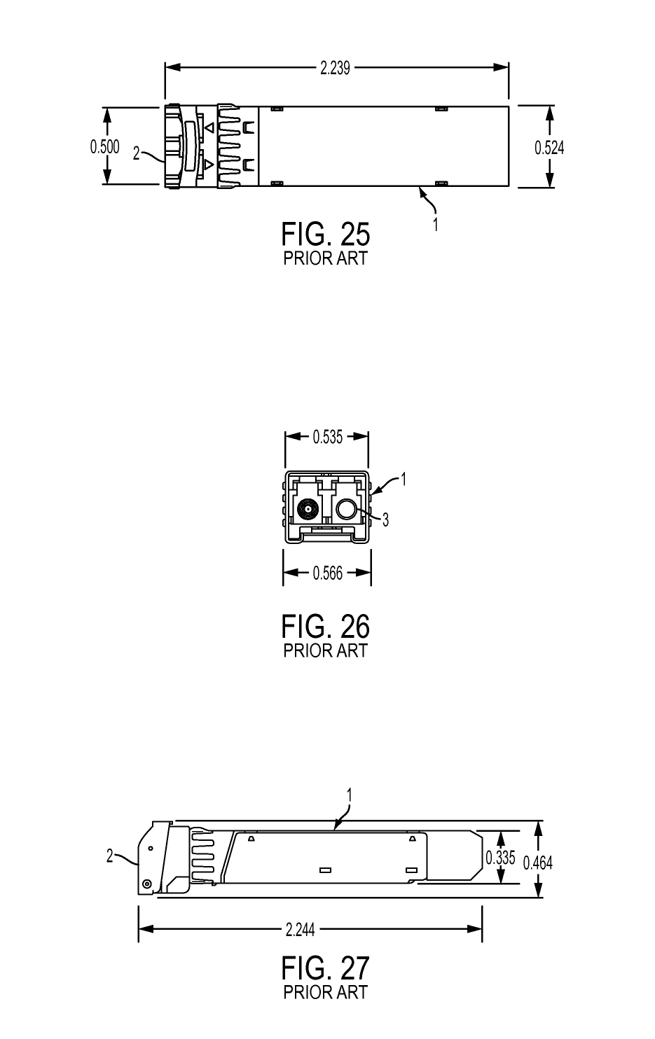

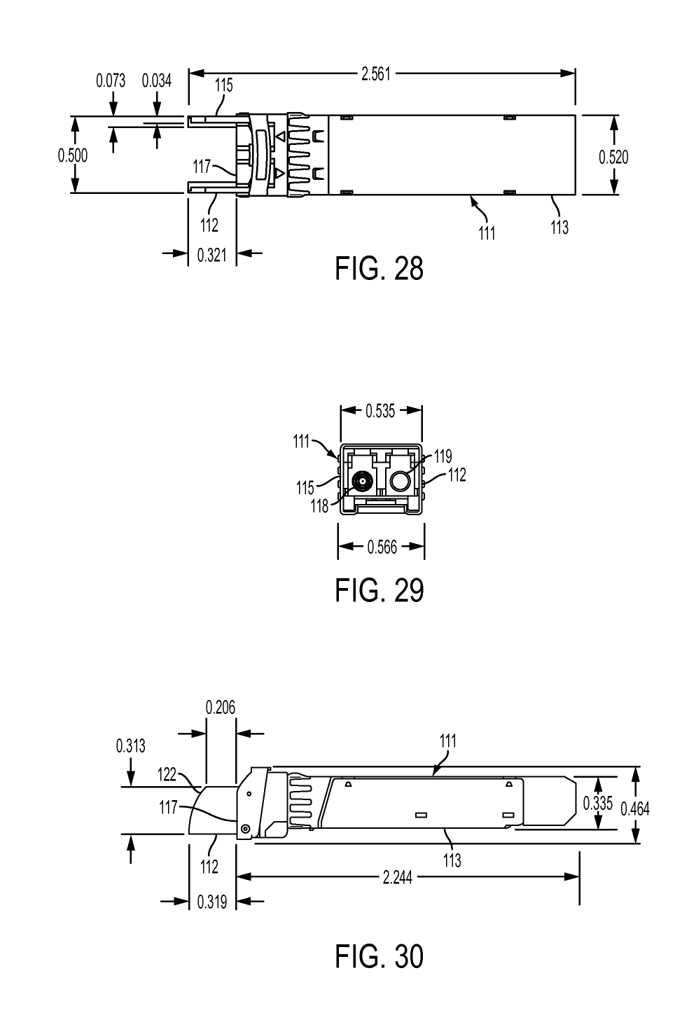

The heat fins 112 and 115 can have any suitable size or shape that increases the surface area of the heat fins to facilitate heat dissipation. Exemplary dimensions for heat fins 112 and 115 are shown in FIGS. 28-30, although the heat fins are not so limited. For example, heat fin 112 is shown having a length of 0.319 inches in FIG. 30, although a heat fin in accordance with the present invention could be longer or shorter. Dimensions of a conventional SFP module 1 are shown in FIGS. 25-27 for comparison.

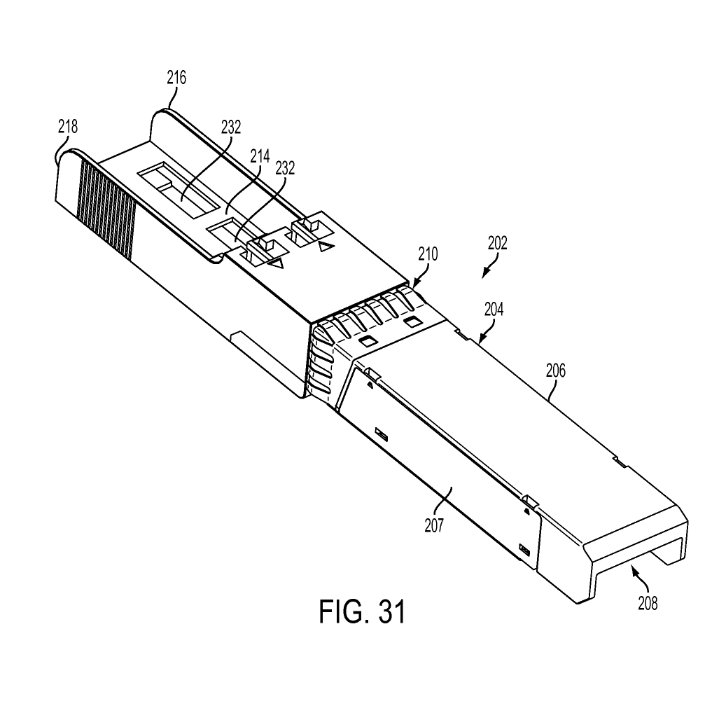

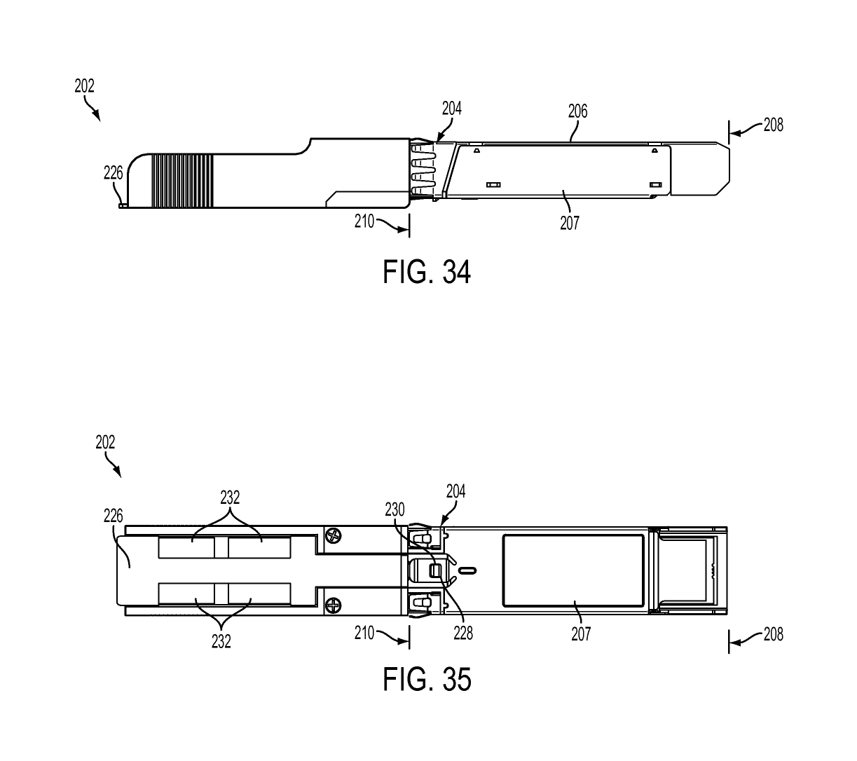

FIGS. 31-41 depict a third illustrative embodiment of a SFP module 202. The third exemplary embodiment is similar to the second embodiment described above in terms of extending the housing of a SFP for heat dissipation but with modifications. For example, the SFP module 202 includes a housing 204 composed of a cover 207, a main body 206, a protruding member 214 and side members 216 and 218.

According to one embodiment, the main body 206 and the cover 207 houses SFP components (not shown) such as, for example, those deployed in conventional SFPs and optionally those deployed in SFPs having non-standard features. The SFP components include, for example, an optical interface and an electrical interface and various electronic and/or electrical components (e.g., semiconductor devices) to operate and control the SFP module 202.

SFP components and heat generation will now briefly be described. A SFP is a compact, hot-pluggable transceiver used for both telecommunication and data communications applications. The form factor and electrical interface and operations of SFPs are specified by a multi-source agreement (MSA) and standardized by the SFF Committee in the SFP specification INF-8074i available at ftp://ftp.seagate.com/sff/INF-8074.pdf, in extensions to the SFP MSA document such as other SFF documents available from the SFF Committee, and in similar specifications for other types of transceivers.

A SFP is plugged into communication equipment, such as switches and routers, to provide a media conversion, such as converting electrical signals to optical for transport over fiber optics. For example, a SFP transceiver interfaces a network device motherboard (for a switch, router, media converter or similar device) to a fiber optic or copper networking cable. SFP transceivers are designed to support SONET, Gigabit Ethernet, Fibre Channel, and other communications standards and have been used for data rates of under 100 Mb/s to over 5 Gbit/s. Other form-factor pluggable transceivers are available which operate at higher rates.

A SFP can also be configured to provide enhanced or non-standard operations such as, for example, a SFP having NID circuitry (hereinafter referred to as a SFP NID). U.S. Patent Application Publication U.S. 2012/0182900, to Davari, which is incorporated herein by reference, describes a type of SFP NID that can be plugged into a SFP cage interfaces. Increased transmission speeds and/or additional operations (e.g., enhanced diagnostics) in SFPs require more processing power and/or more circuit components, which can generate more heat and therefore require heat dissipation.

Illustrative embodiments of the present invention are advantageous because they facilitate heat dissipation, among other benefits such as cable strain relief. The need for SPFs as described herein in accordance with various embodiments of the present invention can only increase as functionality in SFPs advances to meet increasing demands for greater processing power to accommodate higher transmission speeds, more diagnostics, among other functions.

The main body 206, according to one embodiment, includes a first end 208 and a second end 210. The first and second ends 208, 210 are on opposing end surfaces of the main body 206. The first end 208 is configured to engage the cage and corresponding electrical interface of the NID or other device into which the SFP is plugged as described above. The second end 210 of the main body 206 is directly connected to the protruding member 214. The protruding member 214, side members 216, 218 and the main body 206 are preferably composed of 3# zinc alloy, but other materials may be used.

According to one embodiment, the main body 206 is integral to the protruding member 214. For example, the main body 206 and the protruding member 214 can be a single casting or a single machined part. Alternatively, the protruding member 214 can be an extension that is mounted to the main body 206 via a press fit, for example.

As described above, ports 118 and 119 of the SFP module are accessible to connect cables thereto. FIG. 33 similarly illustrates that the second end 210 of the main body 206 also includes ports 238, 240. The interface between the main body 206 and the protruding member 214 is located at a front surface of the ports 238, 240.

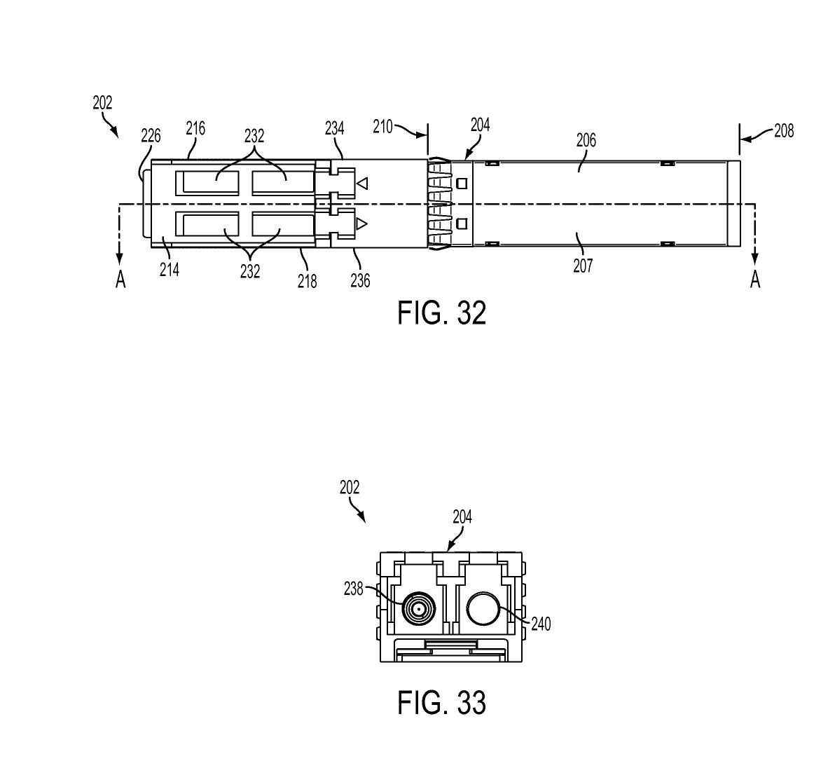

The protruding member 214 in the third exemplary embodiment is an extension of the heat fins 112, 115 described in the above-described second embodiment shown in FIGS. 12-20. The protruding member 214 is, for example, of a rectangular shape, although other shapes can be used. The protruding member 214 can be a solid sheet of material or preferably provided with openings 232 as shown in FIGS. 31 and 32 for increased air flow around the protruding member 214 and housing 204. Therefore, better heat dissipation from heat generated, for example, by components in the main body 206 is achieved.

The length of the protruding member 214 can vary depending on the following exemplary factors: the amount of heat dissipation desired; the clearance or space around the device into which the SFP is plugged into; and the desired strain relief for cables. For example, cables connected to a SFP have a bend radius minimum (BRM) to avoid damage. Another factor is the amount of space available between a device into which a SFP plugs and, for example, a distance between the device and a wall or door of a cabinet in which the device is deployed.

For example, the protruding member 214 can extend up to three inches from the interface between the main body 206 and the protruding member 214. Preferably, the protruding member 214 extends a length of approximately 0.5 inches to 1.5 inches from the main body 206. More preferably, the protruding member 214 extends a length of approximately 1 inch. In all cases, the heat fins may be designed to be as long as possible without interfering with the ability to install the SFP in its intended application.

Various industries, such as telecommunications, publish clearance standards for such installations. The length of the protruding member is selected to obtain maximum heat dissipation without affecting space or human form factor issues (e.g., allowing for easy human installation of SFP within typical deployment environment) while taking advantage of the generally inflexible strain relief found on fiber jumpers. The BRM is based upon the fiber leaving such strain reliefs and therefore the heat fins may be as long as the strain relief without impinging upon BRM such that the SPF module 202 does not require any more space than is typically required by the cables connected to the SFP.

According to one embodiment, the housing 204 further includes two side members 216, 218 as illustrated in FIGS. 31 and 32. Similar to the protruding member 214, the side members 216, 218 also extend from the second end 210 of the main body 206. The side members 216, 218 are substantially parallel to each other and are each substantially perpendicular to the protruding member 214. Specifically, the side members 216, 218 are disposed on opposing side surfaces of the protruding member 214. As a result, the side members 216, 218 and the protruding member 214 form a partial enclosure that routes, supports and protects cables that are connected to the ports 238, 240. The considerations for the lengths of the side members 216 and 218 are the same as the factors described above in connection with the length of the protruding member 214.

The protruding member 214, according to one embodiment, is integral to the two side members 216, 218. For example, the protruding member 214 and the two side members 216, 218 can be of a single casting or a single machined part. Alternatively, the two side members 216, 218 can be a separate piece that acts as an extension. In this manner, the two side members 216, 218 are mounted to the main body 206 via a press fit, for example.

The configuration of the protruding member 214 and the two side members 216, 218 increases the surface area of the SFP module 202. As a result, the SFP module 202 achieves increased air flow and improved dissipation of heat produced from the SFP components. Additionally, the increased length of the protruding member 214 provides additional strain relief to the cables connecting to the ports 238, 240. The protruding member 214 does not impede the routing of cables and provides an increased surface to support and protect the cables. Also, the configuration of the protruding member 214 and the two side members 216, 218 also aligns the cables, which is beneficial for optic communications.

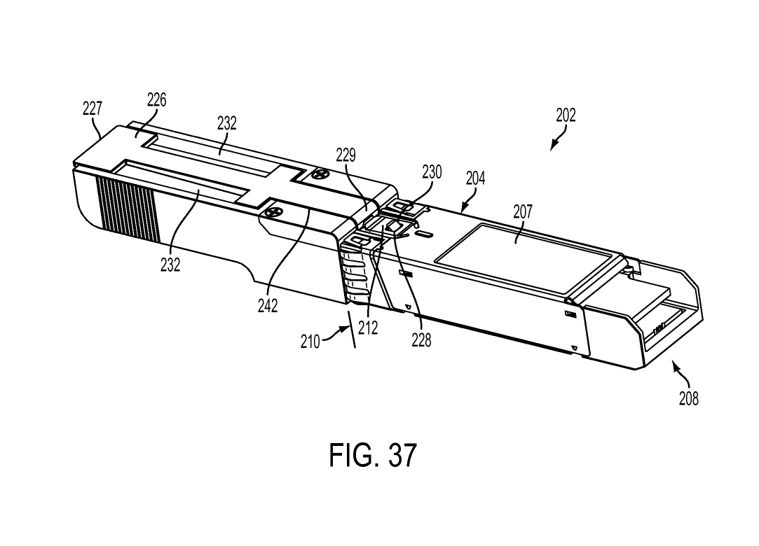

According to one embodiment, FIGS. 37-40 illustrate a release member 226 in the SFP module 202. The release member 226 is connected to the protruding member 214 and is configured to allow a user to engage and disengage the SFP module 202 from the SFP cage.

The release member 226 is preferably made of 3# zinc alloy although other suitable materials may be used. The release member 226 is a lever that travels along an underside of the SFP module 202. Specifically, an underside of the main body 206 includes a passage 242. The release member 226 is disposed inside the passage 242. The passage 242 centrally positions and aligns the release member 226 with respect to the main body 206.

The cover 207 comprises an extending tab 212 with a slot 228. The release member 226 includes a curved portion 229 at a first end thereof that is disposed within the passage 242 in the main body 206. The curved portion 229 has at least a portion thereof disposed between the extending tab 212 and a designated area on the surface of the main body 206 to anchor the first end of the release member 226. The curved portion 229 causes a second end 227 of the release member 226 to be a cantilever member. Accordingly, when the second end 227 of the release member 226 is displaced (e.g., via a cantilever movement), the curved portion 229 cooperates with the extending tab 212 and slot 228 to alternately disengage a protrusion 230 and therefore the SFP module 202 from the cage as described in further detail below.

The release member 226 includes the protrusion 230 on the underside of the SFP module 202. The protrusion 230 is sized to fit inside the slot 228 of the extending tab 212 of the cover 207. As described below, the protrusion 230 cooperates with the slot 228 during operation of the release member 226.

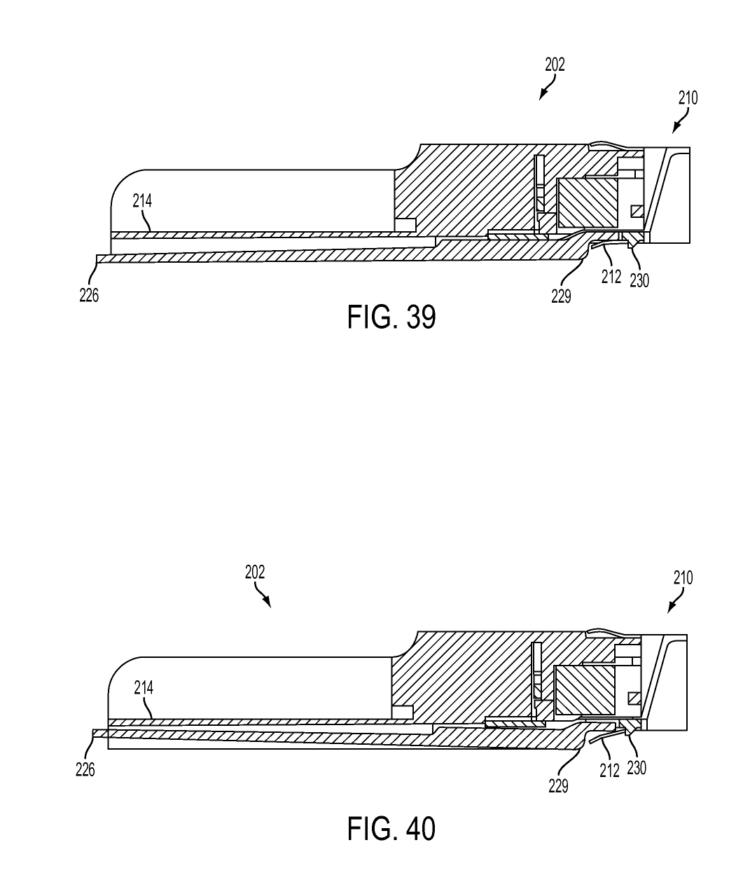

FIG. 39 illustrates an exemplary first position where the release member 226 is in a free state. When the release member 226 is disposed in the passage 242 in the first position, and the slot 228 and the protrusion 230 are engaged. The release member 226 is secured to the SFP module 202, and the SFP module 202 is configured to engage the cage. Specifically, the protrusion 230 in the release member 226 engages the cage (not shown) to secure the SFP module 202 inside the cage.

FIG. 40 illustrates an exemplary second position when the user depresses the release member 226. Upon depressing the release member 226 upward from the first position as described above, the extending tab 212 with slot 228 travels downward. FIGS. 39 and 40 illustrate the cantilever movement of the release member 226 between the first and second positions. When the extending tab 212 with slot 228 travels downward, the protrusion 230 of the release member 226 disengages from the slot 228. Accordingly, the protrusion 230 disengages from the cage (not shown) and allows the user to remove the SFP module 202 from the cage.

As illustrated in FIGS. 39 and 40, the release member 226 preferably extends beyond a length of the protruding member 214 identified by a gap. More preferably, the release member 226 extends approximately 0.05 inches from an end of the protruding member 214 that is distant from the parts 238, 240. The gap between the end of the release member 226 and the end of the protruding member 214 can range between 0.02-0.5 inches, for example. The gap between the release member and the protruding member is designed to provide easy SFP installation and easy removal by using the latch, while providing a mechanical latch that prevents the SFP from being accidentally removed during normal operation.

Moreover, the release member 226 is a longer length than a length of the protruding member 214. This configuration advantageously allows the user to access and depress the release member 226 in difficult to reach positions of an assembled demarcation panel. As a result, it is easier for the user to insert and remove the SFP module 202 from the cage.

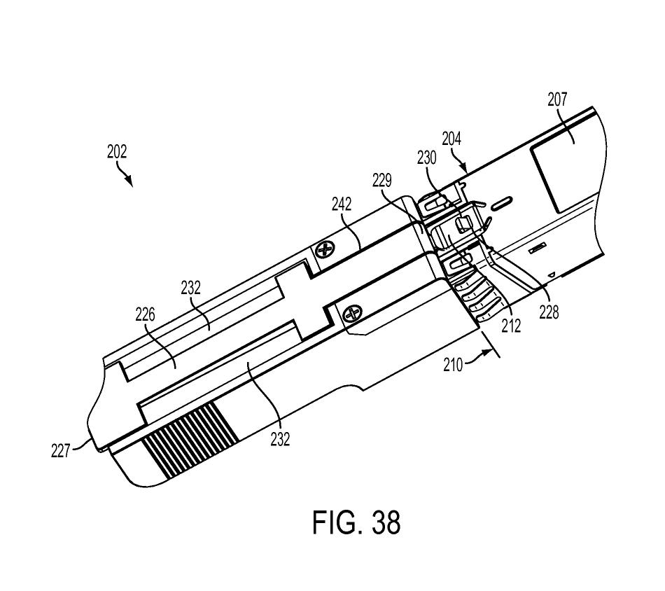

The release member 226 can be a solid member (e.g., a rectangular sheet if material) but can also have cutouts as shown in FIG. 38, wherein the release member has an “H” shape as opposed to a solid rectangular shape. The cutouts can coincide at least in part with the openings 232 in the protruding member 214 to provide an increase in exposed surface area and more air flow. Preferably, the release member 226, protruding member 214 and the main body 206 are made of conductive materials. Because the release member 226 is in contact with the main body 206 and they are both made of conductive materials, heat can be thermally transferred from the main body 206 where the SFP components are stored to the release member 226. Accordingly, the openings 232 can further improve the dissipation of heat from the SFP module 202.

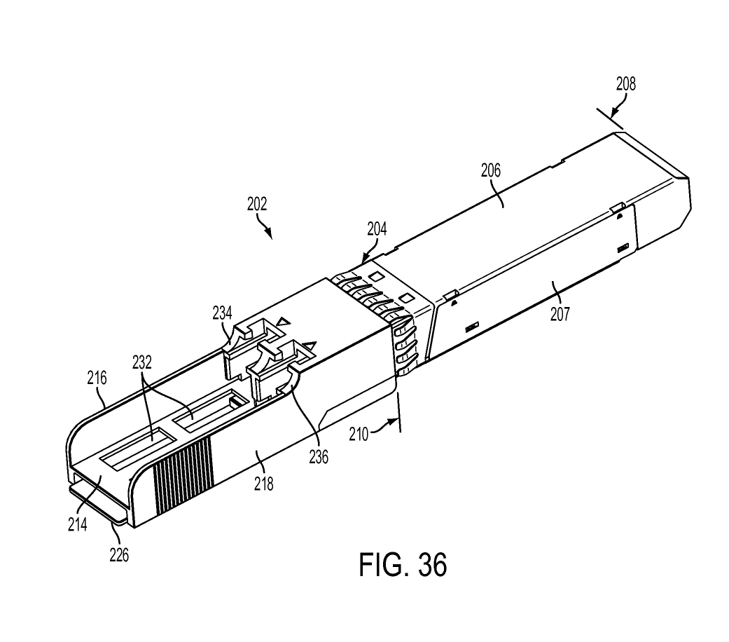

FIGS. 32 and 36 illustrate that the housing 204, according to one embodiment, includes shoulders 234, 236. The shoulders 234, 236 are disposed between the protruding member 214 and the main body 206. Each of the side surfaces 216, 218 is substantially inline to each of the shoulders 234, 236. The shoulders 234, 236 are substantially perpendicular to the protruding member 214 and are arranged on opposing side surfaces. Sharp bends in the cables are minimized via the shoulders 234, 236. As result, the integrity of the cables at the ports 238, 240 is maintained. The shoulders 234, 236 provide advantages such as improved heat dissipation, strain relief and cable support for the cables that connect to the ports 238, 240.

In a fourth embodiment, the SFP module 202 includes the features of the third embodiment with the following modifications. The release member 226 is replaced with the latch 121 illustrated in FIG. 23 of the second embodiment. The latch 121 operates similarly as described above. However, the length of the latch 121 is extended in the fourth embodiment beyond the length of the protruding member 214, for example. Front edges of the side surfaces 216, 218 include a radius to allow the latch 121 to rotate. Latch arms 129 and 130 can be mounted to outer surfaces of the side members 216 and 218.

In operation, the latch 121 rotates about hinge points 128 arranged opposite each other on the side surfaces 216, 218 respectively. Unlike the latch 121 illustrated in FIG. 23 which pivots approximately 90 degrees to allow the SFP module 111 to disengage from the cage, the latch 121 connected to the SFP module 202 pivots along a smaller arc so as not to exceed the height of the SFP module 202 to disengage the SFP module from the cage. The hinged ends of the latch arms 129 and 130 can be configured to bias the SFP module away from the cage and the latch 121 in which the SFP module is mounted as the latch 121 is pivoted. The length of the latch 121 in the fourth embodiment extends beyond the length of the protruding member 214 to allow for the latch 121 to rotate and operate in the manner described above.

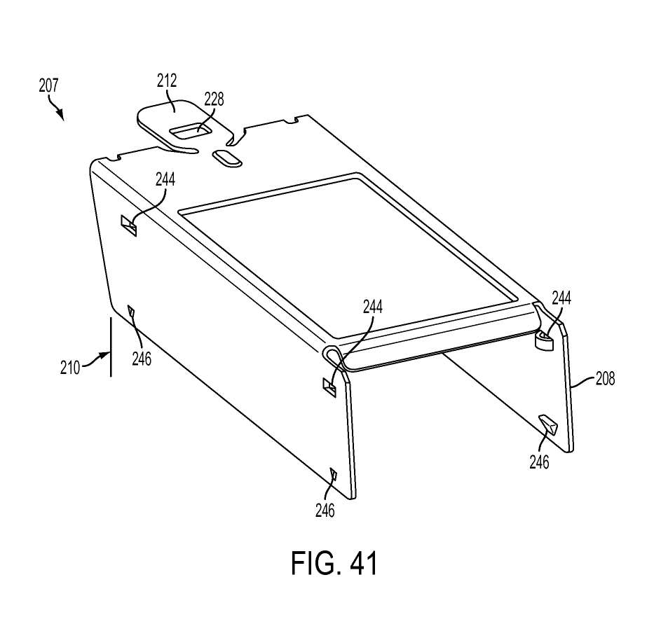

FIG. 41 illustrates an exemplary cover 207 that protects the main body 206. The cover 207 is a separate piece that attaches to the main body 206. The cover 207 substantially encloses the main body 206 on at least three side surfaces.

According to one embodiment, the cover 207 fits into indentations in the main body 206 via tabs 244, 246. The tabs 244, 246 properly align the cover 207 to the main body 206. Specifically, the tabs 244 rest on top of the pc board and secure the pc board in place. Tabs 246 secure the cover 207 to the main body 206 via indentations in the main body 206. The tabs 246 and the indentations provide a friction fit between the main body 206 and the cover 207.

The cover 207 including the extending tab 212 and the slot 228 cooperates with the protrusion 230 of the release member 226. The manner in which the release member 226 operates with the extending tab 212 and slot 228 is discussed above.

In an alternative embodiment, the cover 207 can be integral to the main body 206. Specifically, the extending tab 212 and the slot 228 are part of the main body 206 and cooperate with the protrusion 230 of the release member 226.

The cover 207 is preferably made of a 300 series stainless steel such as 304SS. 300 series stainless steel provides spring-like properties that aid in the release functionality of the SFP module 202, specifically between the cover 207 and the release member 226. The use of a spring-like material allows the extending tab 212 to deflect upon depression and return to a natural free state when no force is applied.

While advantageous embodiments have been chosen to illustrate the invention, it will be understood by those skilled in the art that various changes and modifications may be made therein without departing from the scope of the invention.

What is claimed is:

1. A small-form pluggable optical transceiver (SFP) device comprising:
a housing including:
a main body that houses SFP components, and
at least one protruding member that dissipates heat generated from the SFP components, wherein
the protruding member extends beyond the main body of the housing.

2. The device of claim 1, wherein
the SFP components include at least one of an optical interface, an electrical interface and electrical components.

3. The device of claim 1, wherein
a first end of the main body of the housing is configured to engage a cage, and
a second end of the main body of the housing directly connects to the protruding member.

4. The device of claim 3, wherein
the first and second ends of the main body of the housing are opposing surfaces.

5. The device of claim 1, wherein
the protruding member extends beyond an inch from the main body of the housing.

6. The device of claim 1, wherein
the protruding member is of a substantially rectangular shape.

7. The device of claim 1, wherein
the housing includes two side members that extend beyond the main body of the housing,
the side members are substantially parallel to each other, and
the side members are disposed on opposing side surfaces of the protruding member.

8. The device of claim 1, further comprising:
a release member that is engaged with the protruding member, wherein
the release member is configured to (1) engage a cage to secure the housing to the cage, and (2) disengage the cage to release the housing from the cage.

9. The device of claim 8, wherein
the release member includes a slot,
the main body includes a protrusion, and
the slot and the protrusion are engaged when the housing is engaged to the cage.

10. The device of claim 9, wherein
the release member is a lever that is configured to disengage (1) the slot from the protrusion and (2) the cage from the housing when the release member is depressed.

11. The device of claim 8, wherein
a length of the release member extends beyond a length of the protruding member.

12. The device of claim 8, wherein
the release member comprises a metal.

13. The device of claim 8, wherein
the release member includes a plurality of openings for heat dissipation.

14. The device of claim 8, wherein
a length of the release member is greater than a length of the protruding member.

15. The device of claim 1, wherein
the housing further includes a shoulder that is disposed between the protruding member and the main body to provide heat dissipation and strain relief.

16. The device of claim 15, wherein
the shoulder is substantially perpendicular to the protruding member.

17. The device of claim 1, further comprising
a latch configured to engage and disengage the main body and a cage.

18. The device of claim 17, wherein
a length of the latch extends beyond a length of the protruding member.

19. The device of claim 17, wherein
the latch is rotatably connected to the main body.
